(19) United States
(12) Patent Application Publication
(10) Pub. No.: US 2026/0287665 A1
(43) Pub. Date: Sep. 24, 2026

(54) CIRCUIT ARRANGEMENT AND METHOD FOR THE EXCITATION OF IMPEDANCE SPECTROSCOPY IN MULTICELLULAR BATTERIES

(71) Applicant: Infineon Technologies AG, Neubiberg (DE)

(72) Inventors: Guenter Hofer, St. Oswald (AT); Karl-Ragmar Riemschneider, Hamburg (DE); Tobias Frahm, Hamburg (DE); Florian Rittweger, Hamburg (DE); Thorben Schüthe, Hamburg (DE)

(21) Appl. No.: 19/556,946

(22) Filed: Mar. 4, 2026

(30) Foreign Application Priority Data
Mar. 21, 2025 (DE) 102025111078.6

(51) Int. Cl. G01R 31/389; G01R 31/36; G01R 31/385; G01R 31/396; H02J 7/54

(52) U.S. Cl. CPC G01R 31/389; G01R 31/3644; G01R 31/385; G01R 31/396; H02J 7/54

(57) ABSTRACT

A method is described that comprises the step of switching on a plurality of switching elements coupled to a battery at corresponding switch-on times within a predetermined time period, thereby generating a current signal through the battery. The battery comprises a plurality of battery cells and each switching element of the plurality of switching elements is arranged in parallel with at least one battery cell of the plurality of battery cells. The switch-on times are determined by a controller circuit. The method also comprises the step of measuring a voltage signal over the battery. Further, the method comprises the step of determining an impedance of the battery based on the measured voltage signal and on the generated current signal.

### TECHNICAL FIELD

This application relates to the field of multi-cell battery, in particular to the monitoring of multi-cell batteries using electrochemical impedance spectroscopy.

### BACKGROUND

Multi-cell batteries are widely employed in electric vehicles. They comprise a large number of battery cells, e.g. lithium-ion batteries, that are connected to each other. Typical multi-cell batteries comprise several hundreds of battery cells and can yield voltage levels of 400 V or 800V.

In order to obtain useful information about the battery condition, such as state of charge, performance prediction, or temperature, the multi-cell battery may be monitored by electrochemical impedance spectroscopy. Electrochemical impedance spectroscopy is a diagnosis method that makes it possible to predict the power that is available in the near future. Conventionally, the multi-cell battery is excited by an exterior circuit applying sinusoidal signals to the battery and the impedance of the battery is measured.

However, conventional electrochemical impedance spectroscopy is energy-consuming and requires additional hardware. In particular, either a current measurement synchronous with the voltage measurement is required or a precise knowledge of the time and amplitude behavior of the excitation is necessary.

Accordingly, a need for an improved method for monitoring a multi-cell battery has been identified that is energy-saving and does not require any additional hardware.

### SUMMARY

The above-mentioned objective is achieved by the method of claim 1, in particular by switching on the balancing switches of the multicell battery at corresponding predetermined switch-on times, as well as by the system of claim 15. By controlling the switching operations of a plurality of balancing switches of the battery, the load of the multi-cell battery can be modulated and a periodical excitation current can be generated in the battery. This excitation current can be used to determine the complex impedance of the battery. Since the switching elements are part of the existing hardware of battery management systems, there is no need to add further circuitry. Further, the switch-on times can be determined such as to obtain variable signal shapes for the excitation current.

In one example, the disclosure is directed to a method comprising the step of switching on a plurality of switching elements coupled to a battery at corresponding switch-on times within a predetermined time period, thereby generating a current signal through the battery. The battery comprises a plurality of battery cells and each switching element of the plurality of switching elements is arranged in parallel with at least one battery cell of the plurality of battery cells. The switch-on times are determined by a controller circuit. The method also comprises the step of measuring a voltage signal over the battery. Further, the method comprises the step of determining an impedance of the battery based on the measured voltage signal and on the generated current signal.

In another example, the disclosure is directed to a system comprising a battery, wherein the battery comprises a plurality of battery cells. The system further comprises a plurality of switching elements coupled to the battery. Each switching element of the plurality of switching elements is arranged in parallel with at least one battery cell of the plurality of battery cells. The system also comprises a controller circuit coupled to the plurality of switching elements. The controller circuit is configured to switch on, at corresponding switch-on times of a predetermined time period, the plurality of switching elements, thereby generating a current signal through the battery, wherein the switch-on times are determined by the controller circuit. The controller circuit is further configured to measure a voltage signal over the battery and determine an impedance of the battery based on the measured voltage signal and the generated current signal.

### BRIEF DESCRIPTION OF THE DRAWINGS

The embodiments described herein can be better understood with reference to the following description and drawings. The components in the figures are not necessarily to scale, emphasis instead being placed upon illustrating the principles of the embodiments. Furthermore, in the figures, like reference numerals designate corresponding parts. In the drawings:

FIG. 1 illustrates the general structure of a multi-cell battery system, in accordance with one or more techniques described herein.

FIG. 2 illustrates a first example circuit of a multi-cell battery system, in accordance with one or more techniques described herein.

FIG. 3 illustrates the structure of a multi-cell battery system that comprises a plurality of local controllers linked as a daisy chain, in accordance with one or more techniques described herein.

FIG. 4 illustrates a second example circuit of multi-cell battery system with a plurality of local controllers, in accordance with one or more techniques described herein.

FIG. 5 illustrates an example of a circuit comprising a balancing device for carrying out a diagnosis of battery cells of a multi-cell battery, in accordance with one or more techniques described herein.

FIGS. 6a and 6b illustrate a simplified circuit comprising a balancing circuit for a battery cell when the switching element is switched off (FIG. 6a) and when the switching element is switched on (FIG. 6b).

FIG. 7 illustrates a first example of switching operations of a plurality of switching elements (region (a)), of the balancing signal (region (b)) and of the cumulated switching operations (region (c)), in accordance with one or more techniques described herein.

FIG. 8 illustrates a second example of switching operations of a plurality of switching elements (region (a)) and of the balancing signal (region (b)), in accordance with one or more techniques described herein.

FIG. 9 illustrates a third example of switching operations of a plurality of switching elements (region (a)) and of the balancing signal (region (b)), in accordance with one or more techniques described herein.

FIGS. 10a and 10b illustrate a fourth example of switching operations of a plurality of switching elements (shown in FIG. 10a) and of the balancing signal (shown in FIG. 10b), in accordance with one or more techniques described herein.

FIG. 11 illustrates time diagrams of the load resistance of a multi-cell battery for different patterns of the switch-on times, in accordance with one or more techniques described herein.

FIG. 12 is a flowchart illustrating an example method for measuring the impedance of a multi-cell battery, in accordance with one or more techniques described in this disclosure.

### DETAILED DESCRIPTION

Multi-cell batteries are widely used in electrical cars. They comprise a plurality of battery cells that are connected to each other. In order to enable in-depth battery analysis, the multi-cell batteries are conventionally used in combination with battery management systems. The battery management system is configured to, amongst other functions, provide battery state estimation and measure cell parameters, such as voltage, current, and temperature.

Balancing circuits are important components of the battery management system. They are used to balance the charge of a battery cell or a group of battery cells, thus enabling an individual diagnosis of the battery cells. Balancing circuits comprise a resistor (also called balancing resistor) and a switching element. Balancing circuits are regularly found in large lithium-ion batteries, but they can also be used in other types of battery. The balancing circuits are connected to a controller circuit that is configured to control the balancing circuits and, in particular, the switching on and off of the switching elements. Each balancing switch may be individually controlled.

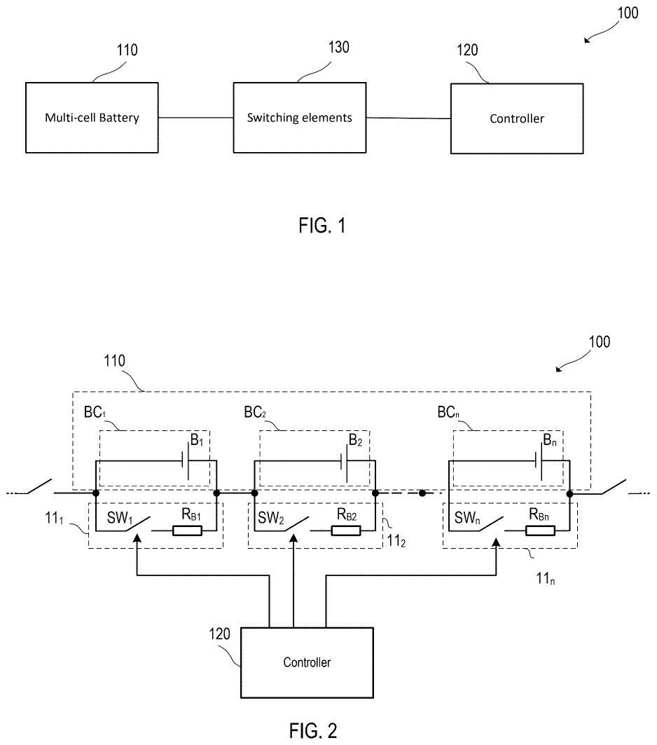

FIG. 1 illustrates an example of an overall structure of a multi-cell battery system 100. The system comprises a multi-cell battery 110, which comprises a plurality of battery cells. In one example, the battery is a 400 V or 800 V battery. The battery 110 may comprise several hundreds of individual battery cells connected in series to each other. In one example, the battery comprises 180 battery cells, wherein each battery cell generates a DC voltage level of 4.2 V, thereby yielding an overall DC voltage level of 756 V. In one example, the battery cells comprise a single battery element. In another example, at least one of the battery cells comprises a plurality of battery elements connected in parallel to each other.

The system 100 comprises a plurality 130 of switching elements coupled to the battery 110 and a controller 120 coupled to the plurality 130 of switching elements. The system 100 may also comprise a plurality of balancing resistors, wherein each switching element of the plurality 130 of switching elements is arranged in series with at least one balancing resistor of the plurality of balancing resistors. The switching elements and the balancing resistors are part of corresponding balancing circuits, as will be shown below with reference to FIGS. 2 to 6. In one example, the controller circuit 120 is configured to switch on the plurality 130 of switching elements. The controller circuit 120 and the plurality 130 of switching elements are part of the battery management system of the multi-cell battery 110.

In one example, the controller circuit 120 is partly software-implemented using an appropriate processor (e.g., a microcontroller). The processor may be configured to execute instructions of the software that are stored in a memory. In another example, the controller circuit 120 is fully hardware-implemented and does not need a programmable processor. The controller circuit 120 may also be implemented as a combination of hardware and software.

FIG. 2 illustrates a first example of the multi-cell battery system 100 in a more detailed manner. The multi-cell battery 110 comprises a plurality n of battery cells BC₁ . . . BCₙ that are connected in series to each other. As mentioned above, the battery cells BC₁ . . . BCₙ may comprise a single battery element B₁ . . . Bₙ or a plurality of battery elements arranged in parallel Each battery element B₁ . . . Bₙ may comprise an internal resistor (not shown). The system 100 also comprises a plurality of balancing circuits 11₁ . . . 11ₙ, wherein each of the balancing circuits 11₁ . . . 11ₙ is connected to a corresponding one of the battery cells BC₁ . . . BCₙ. In the depicted example, each balancing circuit 11₁ . . . 11ₙ comprises at least one switching element SW₁ . . . SWₙ and at least one balancing resistor R_{B1}, R_{B2}, . . . , R_{Bn}. The switching element and the balancing resistor of each balancing circuit 11₁ . . . 11ₙ are connected in series. The controller circuit 120 is coupled to the plurality 130 of switching elements SW₁ . . . SWₙ and configured to control the switching elements SW₁ . . . SWₙ. In the depicted example, the battery 110 is shown in a state in which the battery 110 is decoupled from external currents and no current flows through the battery 110. In this state, the battery 110 may be monitored by the controller circuit 120. In one example, the battery 110 does not have any external load. This is schematically illustrated by open switching elements at both ends of the battery 110.

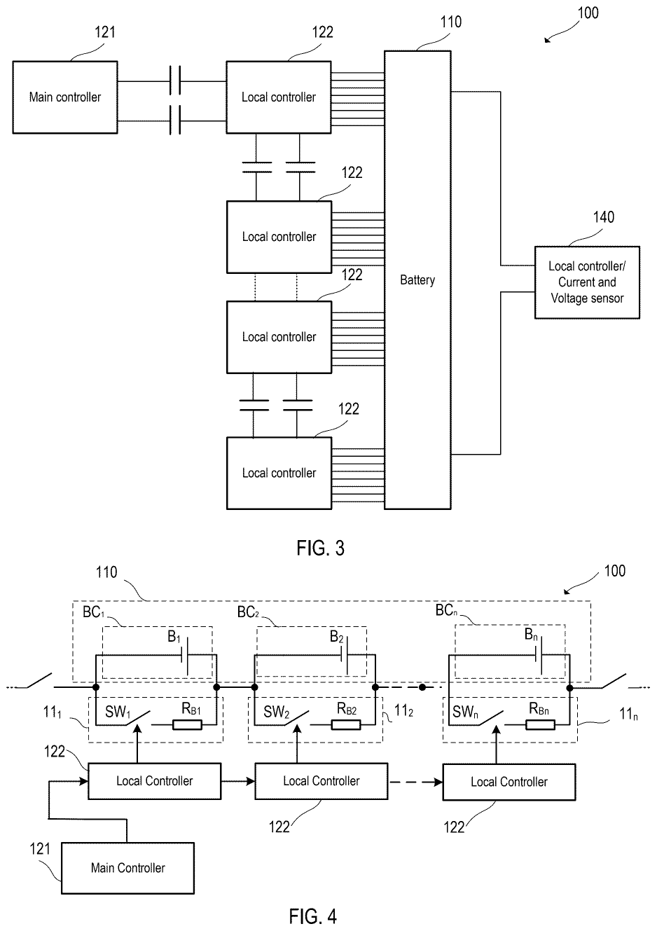

The controller circuit 120 may be a microcontroller configured to directly control each of the switching elements SW₁ . . . SWₙ of the battery 110 by sending corresponding control signals in parallel to the different balancing circuits 11₁ . . . 11ₙ. Alternatively, the switching elements SW₁ . . . SWₙ may be controlled via local controllers arranged in a serial daisy chain. This situation is exemplified in FIG. 3.

FIG. 3 shows the structure of a multi-cell battery system 100 that comprises a plurality of local controllers 122 linked as a daisy chain. In the depicted example, the controller circuit 120 comprises a main controller 121 and the plurality of local controllers 122. A first local controller of the plurality of local controllers 122 is connected to the main controller 121. The local controllers 122 are connected to each other to form a daisy chain, i.e. they are connected to each other in a sequence. The controllers 121, 122 may be galvanically isolated, as schematically illustrated by the capacitors between neighboring controllers. The main controller 121 may comprise a microcontroller in communication with a transceiver, e.g. via a UART interface. The microcontroller may be configured to send a control signal that comprises control signals for all the local controllers 122. The transceiver may be connected to the first controller to transmit the control signals of the micro-controller. The control signals of the microcontroller are then transmitted from one local controller to the next one, wherein each local controller 122 is configured to control at least one switching element of a balancing circuit for a battery cell based on the control signal. The local controller may also be configured to send messages back to the main controller via the daisy chain. The local controllers 122 may have a microcontroller. However, this is not necessary. In one example, the local controllers 122 are integrated circuits. In one example, the local controllers 122 are integrated circuits of the type TLE9012DQU, wherein each local controller 122 is connected to twelve battery cells. In one example, the system comprises ten local controllers 122. In one example, the local controllers 122 are each connected to up to eighteen battery cells of the battery. The local controllers 122 are configured to control the switching elements associated with the connected battery cells based on the control signal of the main controller 121 and to measure local voltages of the battery 110. In one example, the controller circuit 120 comprises a plurality of local voltage sensors, wherein each local voltage sensor is configured to measure a local voltage signal over at least one battery cell of the plurality of battery cells. In addition, the system 100 may comprise a further local controller 140 connected to the battery 110 and configured to measure at least one of a current flowing through the entire battery 110, or a voltage level of the entire battery 110, or both. In one example, the further controller circuit 140 may comprise a microprocessor. In another example, the further controller circuit 140 is fully hardware-implemented and does not need a programmable processor. The further controller circuit 140 may also be implemented as a combination of hardware and software.

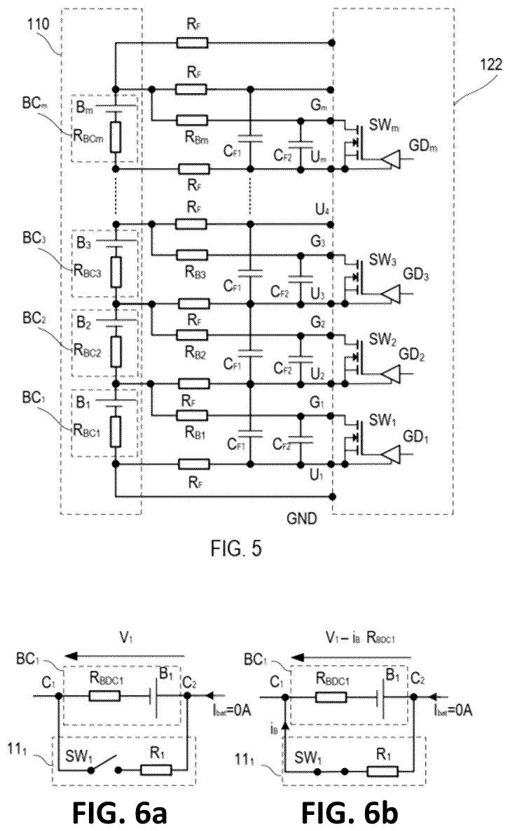

FIG. 4 illustrates a modified example of FIG. 2, in which the controller 120 is replaced with the main controller 121 and the local controllers 122 of FIG. 3. Each local controller 122 is coupled to at least one switching element of the plurality of switching elements SW₁ . . . SWₙ and configured to control the corresponding switching element based on at least a signal of the main controller 121. Each local controller 122 may be connected to one or a plurality of battery cells BC₁ . . . BCₙ. The daisy chain configuration makes it possible to have very short communication delays between the local controllers 122. The communication between a local controller 122 and the corresponding battery cells is explained with further details with reference to FIG. 5.

FIG. 5 illustrates an example circuit for a conventional balancing system of a local controller 122. The local controller 122 is configured to monitor a plurality m of battery cells BC₁ . . . BCₘ. In one example, the local controller 122 is an integrated circuit of the type TLE9012DQU and the integer m is equal to 12. The local controller 122 comprises a plurality of switching elements SW₁ . . . SWₘ. In the depicted example, the switching elements SW₁ . . . SWₘ are MOSFETs. The local controller 122 is configured to control the switching elements SW₁ . . . SWₘ by sending corresponding control signals to gates of the switching elements SW₁ . . . SWₘ via corresponding gate drivers GD₁ . . . GDₘ. However, the switching elements SW₁ . . . SWₘ may also be external to the local controller 122 and connected to the local controller 122 via corresponding pins. As mentioned above, the local controller 122 may be connected to further local controllers 122 via a daisy chain and may receive a control signal from the main controller 121 via the daisy chain.

Each battery cell of the plurality of battery cells BC₁ . . . BCₘ is connected in parallel to a corresponding switching element of the plurality of switching elements SW₁ . . . SWₘ. In the depicted example, each battery cell BC₁ . . . BCₘ comprises a battery element B₁ . . . Bₘ and an internal resistor R_{BC1} . . . R_{BCm}. Each battery cell BC₁ . . . BCₘ is connected to a drain and a source of the corresponding MOSFET SW₁ . . . SWₘ via a first pin U₁ . . . Uₘ and a second pin G₁ . . . Gₘ of the local controller 122, respectively. A corresponding balancing resistor R_{B1} . . . R_{Bm} is arranged between a first terminal of the battery cell BC₁ . . . BCₘ and the second pin G₁ . . . Gₘ. A filter resistor R_{F} is arranged between a second terminal of the battery cell BC₁ . . . BCₘ and the first pin U₁ . . . Uₘ. In addition, the first terminal of the battery cell BC₁ . . . BCₘ is connected to the first pin of the neighbor battery cell via the filter resistor R_{F} of the neighbor battery cell. In one example, the local controller 122 is configured to measure a local voltage drop of the battery cell BC₁ . . . BCₘ between the first pin of the battery cell BC₁ . . . BCₘ and the first pin of the neighbor battery cell. In addition, in order to ensure galvanic isolation, capacitors C_{F1} are connected to the drain and the source of each switching element SW₁ . . . SWₘ and capacitors C_{F2} are connected to the drains of two neighbor switching elements.

The switching elements SW₁ . . . SWₘ may be individually controlled by the local controller 122 for diagnosis purposes. In one example, the local controller 122 sends a balancing signal to a switching element SW₁ . . . SWₘ based on the control signal of the main controller 121. The balancing signal may be a binary signal, wherein the switching element SW₁ . . . SWₘ is configured to be switched on when the balancing signal has a first value and switched off when the balancing signal has a second value. In one example, the balancing signal is a Pulse Width Modulation, PWM, signal. The local controller 122 may monitor a battery cell BC₁ . . . BCₘ by switching on the corresponding switching element SW₁ . . . SWₘ. During the monitoring step, no current flows through the battery 110. When the switching element SW₁ . . . SWₘ is switched on, a balancing current flows through the corresponding battery cell BC₁ . . . BCₘ, the corresponding balancing resistor R_{B1} . . . R_{Bm} and the corresponding filter resistor R_{F}. The voltage level between the first pin of the battery cell BC₁ . . . BCₘ and the first pin of the neighbor battery cell drops by a voltage drop that is proportional to the resistance of the filter resistor R_{F}. The local controller 122 may then measure the voltage drop and determine a diagnosis on the cell based on the measured voltage.

As seen above, the switching elements associated with the battery cells may be controlled individually in order to monitor the battery cells. However, according to one example, the switching elements may be controlled collectively in order to obtain further information on the battery cell.

FIGS. 6a and 6b show a simplified example of a circuit comprising a battery cell BC₁ and a corresponding balancing circuit 11₁ for the battery cell BC₁. The battery cell BC₁ and the balancing circuit 11₁ may be configured as in the example of FIG. 5. The battery cell BC₁ comprises a battery element B₁ and an internal resistor R_{BDC1}. In the depicted example, the battery element B₁ is a voltage source generating a voltage level of 4.2 V. In another example, the battery cell BC₁ comprises a plurality of battery elements arranged in parallel, wherein the voltage level of the battery cell BC₁ is equal to the sum of the voltage levels of the battery elements. In the depicted example, the resistance of the internal resistor R_{BDC1} is 200μΩ. In other examples, the resistance of the internal resistor R_{BDC1} is between 100μΩ and 500μΩ. The balancing circuit 11₁ is connected in parallel with the battery cell B₁. The balancing circuit 11₁ has a switching element SW₁ and a resistor R₁ arranged in series with the switching element SW₁ that represents the overall resistance of the balancing circuit 11₁. In the example of FIG. 5, the resistor R₁ is equivalent to the balancing resistor R_{B1} and the filter resistor R_{F}. The switching element SW₁ may be a transistor, such as a MOSFET. The balancing circuit 11₁ is controlled by a controller circuit 120 (not shown), as illustrated above. The controller circuit 120 may be configured to measure a voltage between terminals C₁ and C₂ of the battery cell BC₁.

FIG. 6(a) illustrates the case in which the switching element SW₁ is switched off. The battery 110 is connected such that there is no battery current I_{bat} through the battery cell B₁, i.e. I_{bat}=0 A. The measured voltage V₁ between the terminals U₁ and U₂ of the battery cell BC₁ is thus equal to the voltage of the battery element B₁, in the present case 4.2 V. FIG. 6(b) illustrates the case in which the switching element SW₁ is switched off. A balancing current i_{B} now flows through the battery cell BC₁. In the depicted example, the balancing current i_{B} is equal to i_{B}=100 mA. In other examples, the balancing current i_{B} is between 50 mA and 250 mA. The voltage between the terminals U₁ and U₂ drops by a voltage drop that is equal to i_{B}·R_{BDC1}=20 μV. When the battery 110 comprises 180 battery cells, the total DC voltage level of the battery 110 is 756 V, the total internal resistance (internal load) of the battery is 36 mΩ, and the maximum voltage drop over the battery 110 is 3.6 mV.

It is thus possible to modulate the internal load of the battery 110 by collectively switching on and off the switching elements of the balancing circuits coupled to the battery 110. The load modulation leads to the generation of an excitation current over the battery 110 which follows the modulations of the load, i.e. if the load has a sinusoidal shape, the excitation current will also have a sinusoidal shape. In one example, the voltage signal is measured over the entire battery 110. In another example, the local voltage signal over each battery cell of the battery 110 is measured. In one example, the excitation current signal is also measured. In another example, the excitation current signal is evaluated based on the known characteristics of the balancing circuits and of the battery cells. Based on the measured voltage signal and on the excitation current signal, the impedance of the battery 110 may be determined. The impedance measurement does not require any additional hardware as the balancing circuits are already available in conventional battery systems. Only the corresponding software needs to be adapted. Further, the power losses can be distributed over the whole battery, thus reducing the power losses compared to a conventional electrochemical impedance measurement.

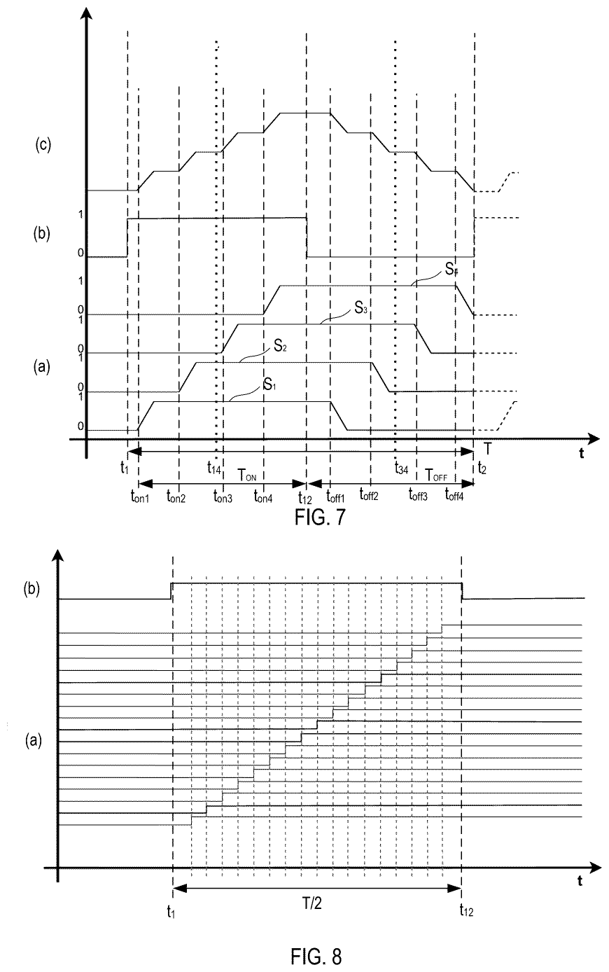

FIGS. 7-10 illustrate how the switching elements of the battery 110 my be switched in order to obtain a desired excitation current through the battery 110. FIG. 7 illustrates a method for controlling the switching operations of a plurality of switching elements during a predetermined time period T. Each switching element is arranged in parallel with at least one battery cell of a multi-cell battery, as shown in the preceding figures. The switching elements may be controlled by the same local controller 122, as shown above with respect to FIGS. 6a and 6b. In another example, the switching elements may be controlled by different local controllers 122.

FIG. 7(region a) shows the switching operations S₁-S₄ of the four switching elements. The value “0 ” indicates that the switching element is switched off and the value “1” indicates that the switching element is switched on. The switching elements S₁-S₄ are switched on at successive switch-on times tₒₙ₁-tₒₙ₄ and switched off at consecutive switch-off times t_{off1}-t_{off4}. A short transition time is needed to transition from the off-state to the on-state of the switching elements. As mentioned above, the switching elements may be controlled by the controller circuit 120, e.g. based on a corresponding control signal. In the depicted example, the switch-on times are determined by the controller circuit 120.

FIG. 7(region b) shows a timing diagram of an operation signal. The operation signal is a binary signal that has a low value, i.e. “0”, that indicates that the switching elements may not be switched on, and a high value, i.e. “1” that indicates that the switching elements can be switched on. In the depicted example, the operation signal has a high value between a beginning time t₁ of the predetermined time period T and time t₁₂, and a low value between a middle time t₁₂ and an ending time t₂ of the predetermined time period T. In the depicted example, the medium time t₁₂ corresponds to half of the predetermined time period T. With this, the switching element are switched on during a first half T_{ON} of the predetermined time period T. Further, the switching elements are switched off during a second half T_{OFF} of the predetermined time period T. This makes it possible to switch on and off the switching elements in a symmetrical manner. However, the operation signal may have a different shape. In one example, the switching element are switched on during a first period of the predetermined time period T and the switching elements are switched off during a second period of the predetermined time period T. In another example, the switching element are switched on during a plurality of first periods of the predetermined time period T. The first periods may be separated by periods in which the switching elements may not be switched on. The first periods may be predetermined. In one example, the first periods may be determined randomly.

FIG. 7(region c) shows the cumulative operations of the switching elements. In the depicted example, the switch-on times are determined such that a first half of the switching elements are switched on during a first quarter of the predetermined time period, namely between times t₁ and t₁₄. In fact, in the depicted example, the switch-on times tₒₙ₁-tₒₙ₄ are evenly distributed within the first half of the predetermined time period. Similarly, the switch-off times t_{off1}-t_{off4} are evenly distributed within the second half of the predetermined time period. In the depicted example, a temporal distance between the switch-off time and the switch-on time of each switching element is equal to the half of the predetermined time period T. In one example, the switch-off times t_{off1}-t_{off4} are determined by the controller circuit 120. In particular, the switch-on times and the switch-off times t_{off1}-t_{off4} may be determined by the main controller 121. In another example, only the switch-on times are determined by the main controller 121. The local controllers 122 are configured to switch off the switching elements after a given switching time. As mentioned above, the given switching time may be equal to half of the predetermined time period T. With this, the switching-on and switching-off operations of the switching elements may be symmetrical with regard to the half-time t₁₂ of the predetermined time period T. In particular, in the depicted example, the switch-off times are determined such that a first half of the switching elements are switched off during a third quarter of the predetermined time period, namely between times t₁₂ and t₃₄.

As mentioned above, the load of a battery cell varies when the corresponding switching element is switched on. The overall load of the battery 110 thus varies according to the shape of the curve in FIG. 7(region c), namely it increases step-wise during the first half of the predetermined time period T, during which the switching elements are successively switched on, and decreases step-wise during the second half of the predetermined time period T, during which the switching elements are successively switched on. The load resistance of the battery thus has a shape that approximates a triangular shape. In addition, a current signal is generated through the battery 110, which also has an essentially triangular shape. The load resistance curve determines the shape of the current flowing through the battery 110.

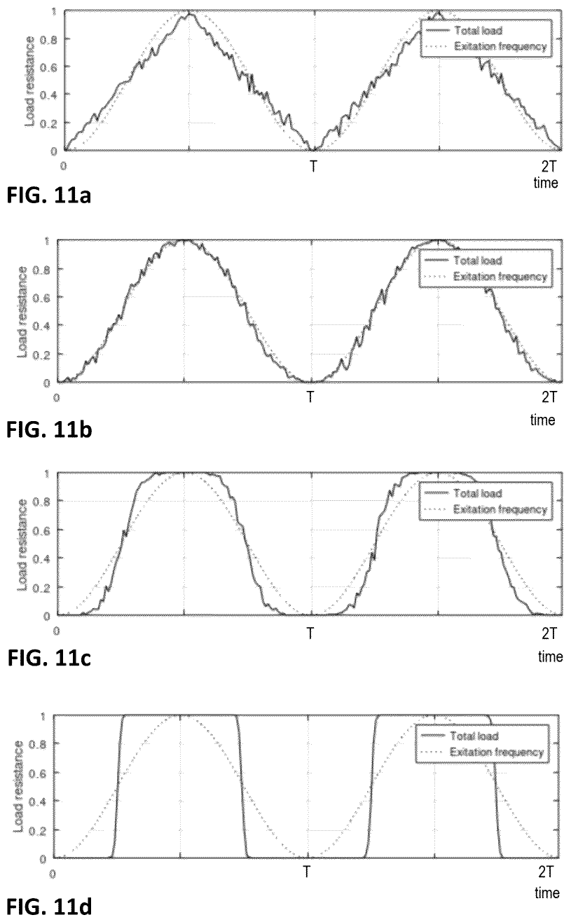

The switching operations may be repeated several times. The load resistance and the current signal will then have a periodical shape, wherein the frequency of the signal is the reciprocal of the predetermined time period T of FIG. 7. Reference is made to FIG. 11(a), which shows the load resistance of the overall battery 110 over time. The load resistance has a triangular shape. It is thus possible to generate a periodical excitation current through the battery 110 by controlling the switching operations of the switching elements coupled to the battery 110. The voltage signal can be measured over the battery 110, and the impedance of the battery 110 can be determined based on the measured voltage signal and on the generated current signal. In one example, the overall voltage is measured by the external voltage sensor 140. In another example, the controller circuit 120 comprises a plurality of local voltage sensors, wherein each local voltage sensor is configured to measure a local voltage signal over at least one battery cell of the plurality of battery cells. The local voltage sensor may be configured to measure a voltage over the corresponding battery cell and the corresponding further resistor of the balancing circuit, as explained above with reference to FIG. 6. Further, the current signal may be measured by the external voltage sensor 140. However, since all elements of the balancing circuits are known, it is also possible to calculate the current level without using any additional sensors.

It is thus possible to determine the impedance of the multi-cell battery by controlling the switching elements of the balancing device of the battery. Further, the predetermined period of time T may be modified to obtain excitation currents having different frequencies. It is thus also possible to calculate the complex impedance of the multi-cell battery by controlling the switching elements of the system. Since the balancing circuits are already present in conventional systems, this operation can be carried out without any change of the battery system.

The switching elements used to generate the periodical signal may be always the same switching elements. However, in order to prevent wearing of the switching elements, at least some of the switching elements may be changed at each predetermined time period T. In one example, the controller circuit 120 switches the switching elements such that, over a plurality of predetermined time periods T, the switching elements are uniformly loaded. In one example, the controller circuit 120 is configured to associate the determined switch-on times to switching elements of the system. In another example, the determined switch-on times are associated to switching elements pseudo-randomly. The switching elements to be switched on and off may be selected by a pseudo-random generator arranged in the controller circuit 120. Further, in one example, an order, in which the switching elements are switched on and off, is determined by the controller circuit 120. Alternatively, the order, in which the switching elements are switched on and off, is determined pseudo-randomly.

FIG. 7 shows that the excitation signal can be generated by using only four switching elements. However, the number of switching elements is not limited to four and may be lower or higher. The use of a high number of switching elements leads to a better approximation of the desired excitation curve. However, it is clear that the number of switching elements used should be kept as low as possible in order to prevent deterioration of the switching elements and to reduce the overall energy consumption. Further, the controller circuit 120 may be configured to switch on a plurality of switching elements at a determined switch-on time. This makes it possible to design the desired excitation curve very flexibly.

An example of a method of controlling a higher number of switching elements of the system is shown in FIG. 8. FIG. 8(region a) shows switching diagrams for seventeen different switching elements of the plurality of switching elements during half of the predetermined time period. FIG. 8(region a) thus only shows the switching-on operations of the switching elements. As in the example of FIG. 7, the controller circuit 120 determines the switch-on times of the switching elements such that the switch-on times are evenly distributed within the first half of the predetermined time period. Similar to FIG. 7(region b), FIG. 8(region b) shows a timing diagram of the corresponding operation signal. The binary operation signal has a high value during the first half of the predetermined time period, meaning that the switching elements can be switched on during this time period. The switching elements may be switched off in a second half of the predetermined period T such that the switch-off times are evenly distributed within the second half of the predetermined time period T. By repeating this switching pattern, the overall load of the battery may be varied according to a periodical triangular pattern. The resulting excitation current over the battery will also have a triangular shape. Since the switch-on times are evenly distributed, this option is particularly simple from a control point of view. In particular, since the number of switching elements involved in the switching process is higher than in the example of FIG. 7, the triangular shape can be better approximated. As mentioned above, the number of switching elements involved in the switching process may be higher or lower depending on the desired pattern for the excitation current. A higher number of switching elements switched on during the predetermined time period leads to a smoother shape of the excitation signal.

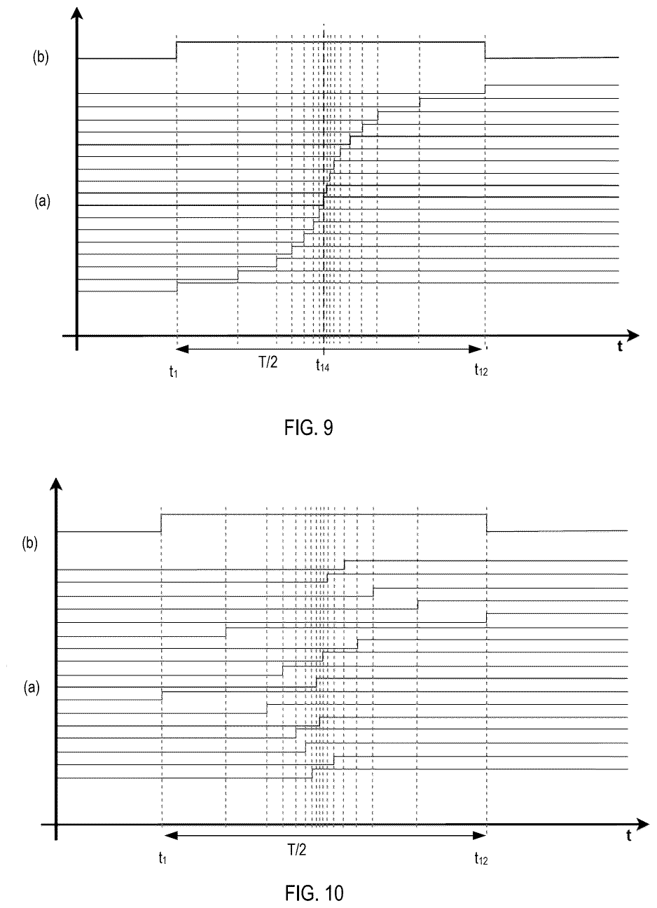

However, it is also possible to obtain other shapes for the excitation current by modifying the distribution of the switch-on times over the predetermined time period T. A further example of a method of controlling a plurality of switching elements of the system is shown in FIG. 9. FIG. 9(region a) shows switching diagrams for seventeen different switching elements of the plurality of switching elements during a first half T/2 of the predetermined time period T. FIG. 9(region a) only shows the switching-on operations of the switching elements. Contrary to the examples of FIGS. 7 and 8, the controller circuit 120 determines, in this example, the switch-on times of the switching elements such that the switch-on times are not evenly distributed within the first half of the predetermined time period. In particular, the controller circuit 120 determines the switch-on times such that a first temporal distance between two first consecutive switch-on times is different from a second temporal distance between two second consecutive switch-on times. The controller circuit 120 may determine the switch-on times based on a predetermined function. In the depicted example, the controller circuit 120 determines the switch-on times such that a temporal distance between two consecutive switch-on times decreases during a first portion of the predetermined time period and increases during a second portion of the predetermined time period. In the depicted example, the first portion is equal to a first quarter of the predetermined time period T, and the second portion is equal to a second quarter of the predetermined time period T. In one example, the temporal distance between two consecutive switch-on times decreases linearly during the first portion of the predetermined time period. The temporal distance between two consecutive switch-on times may also increase linearly during the second portion of the predetermined time period. However, the temporal distances between two consecutive switch-on times may be determined according to other types of mathematical functions. In order to be able to approximate a sinusoidal excitation signal, in the depicted example, a first half of the switching elements are switched on during a first quarter of the predetermined time period T. The end time of the first quarter of the predetermined time period T will then correspond to the zero crossing of the generated periodical current signal.

Similar to FIG. 7(region b) and 8(region b), FIG. 9(region b) shows a timing diagram of the corresponding operation signal. The binary operation signal has a high value during the first half of the predetermined time period T, meaning that the switching elements can be switched on during this time period. The switching elements may be switched off in a second half of the predetermined period, i.e. when the binary operation signal has a low value. In one example, the switching elements are switched off in the same way as the switching elements are switched on. In one example, the switch-off times are unevenly distributed within the second half of the predetermined time period. In particular, a first temporal distance between two first consecutive switch-off times may decrease during a third portion of the predetermined time period and may increase during a fourth portion of the predetermined time period. In one example, a temporal distance between the switch-off time and the switch-on time of each switching element is constant. With this, the switching elements may be uniformly loaded. The temporal distance between the switch-off time and the switch-on time may be equal to the half of the predetermined time period. In another example, the temporal distance between the switch-off time and the switch-on time varies depending on the switching element. This enables a more flexible control of the switching elements.

By repeating the switching pattern of FIG. 9, the overall load of the battery 110 may be varied according to a periodical pattern. The resulting excitation current over the battery 110 will also be periodical. Depending on the function or pattern according to which the switch-on times are determined, the shape of the load curve can be adjusted. Possible shapes of the load curves that can be obtained when the switch-on times are not evenly distributed are shown in FIG. 11(b), 11(c) and 11(d). Depending on the distribution of the switch-on times, a trapezoidal shape or a sinusoidal shape can be approximated. In particular, if the switch-on times decrease more rapidly in the first quarter of the predetermined time period, the slope of the load curve will be steeper. If the switch-on times decrease and increase linearly, the load curve can have a sinusoidal shape.

In the example of FIG. 9, the controller circuit 120 selects, for each predetermined period of time, the switching elements to be switched on and the order, in which they are to be switched on. The controller circuit 120 may also determine the order, in which the selected switching elements are switched off.

FIG. 10 shows switching diagrams for an alternative switching method. In the example of FIG. 10, the order, in which the switching elements are switched on and off, is determined pseudo-randomly. The order may be determined by a pseudo-random generator. Further, the switching elements to be switched on may also be selected pseudo-randomly within the plurality of switching elements of the multi-cell battery. The controller circuit 120 may monitor the switching operations of the switching elements and ensure that the switching elements are uniformly loaded over a plurality of predetermined time periods to prevent degradation of the switching elements. In one example, when the controller circuit 120 determines that a switching element has been loaded, during a number of predetermined time periods, a number of times that exceeds a threshold number of times, the controller circuit 120 sends a signal to the pseudo-random generator that leads the pseudo-random generator not to consider this switching elements for the next impedance measurements.

In one example, at least one of the switch-on times is determined, at least partially, pseudo-randomly. The switch-on time may be determined by the controller circuit 120 according to a desired shape of the excitation signal. In addition, the determined switch-on time may be modified pseudo-randomly. In one example, the determined switch-on time may be modified by a pseudo-random generator of the controller circuit 120. In one example, a variation of the determined switch-on time may be determined pseudo-randomly. A range of the variation or a range of the ratio between the variation and the switch-on-time may be determined by the controller circuit 120. The switch-on time is thus determined both deterministically, i.e. based on a predetermined function, and pseudo-randomly. This leads to the addition of an artificial noise component within the excitation signal, in addition with the natural noise component. The signal-to-noise ratio of the excitation signal depends on the number of switched-on times determined, at least partially, pseudo-randomly. The controller circuit 120 may analyze the excitation signal and calculate the signal-to-noise ratio of the excitation signal. These data can be taken into account by the controller circuit 120 when determining the switch-on times. With this, the signal-to-noise ratio can be reduced over a plurality of predetermined time periods of the excitation signal.

FIG. 11 shows timing diagrams of the load resistance of the multi-cell battery 110 for different switching operations. The plain line shows the load resistance over time during two predetermined time periods T. The dashed line shows the ideal sinusoidal excitation over time. The load resistance value is normalized to 1. FIG. 11(a) shows the load variations resulting in a uniform distribution of the switching-on times. The load resistance of the battery 110 has approximately a triangular shape. The shape of the load resistance curve is, however, not perfectly triangular. This is due to noise, which may be partly natural and partly artificially induced by modifying the switch-on times pseudo-randomly, as explained above. The symmetrical aspect of the load curve is due to the fact that the switching elements are switched on during a first half of each predetermined time period T and switched off during a second half of each predetermined time period T.

FIG. 11(b), 11(c) and 11(d) show load variations resulting in various non-uniform distributions of the switching-on times. The switch-on times decrease in a first quarter of the predetermined time period and increase in a second quarter of the predetermined time period, wherein half of the switching elements are switched on during the first quarter of the predetermined time period. With this, a periodical sinusoidal excitation signal can be approximated. In the example of FIG. 11(b), the switch-on times decrease and increase linearly. The resulting load resistance curve has a shape that is very similar to that of a sinusoidal signal. In the example of FIG. 11(c), the switch-on times decrease and increase more rapidly than in the example of FIG. 11(b). The resulting load resistance curve has a steeper slope than in FIG. 11(b). In the example of FIG. 11(d), the switch-on times decrease and increase even more rapidly than in the example of FIG. 11(c). The resulting load resistance curve has a trapezoidal shape with a very steep slope that approximates an edge signal.

It is thus possible to obtain all possible types of load curves depending on the determination of the switched-on times of the switching elements of the balancing circuits. The load curve determines the signal shape of the excitation current which can be used for the impedance measurement.

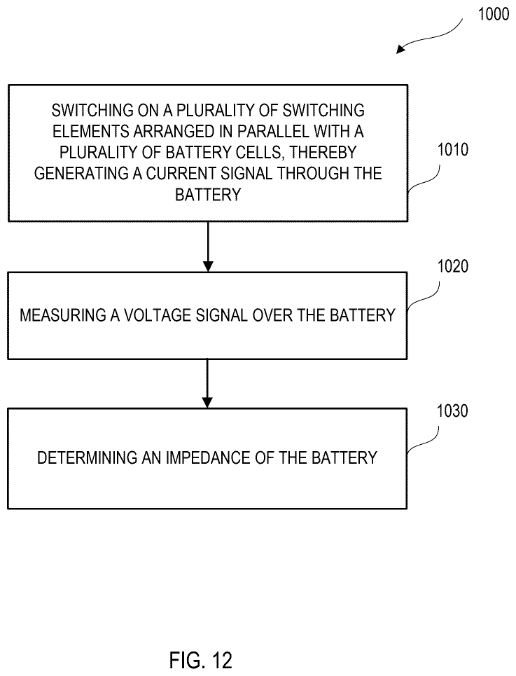

FIG. 12 is a flowchart illustrating an example method 1000 for controlling a system 100 comprising a multi-cell battery 110.

The example process 1000 can be employed to operate devices illustrated in this disclosure, such as the system according to FIG. 2 or the system according to FIG. 5.

Process 1000 comprises the step 1010 of switching on a plurality 130 of switching elements S1, S2, . . . , Sn coupled to a battery 110 at corresponding switch-on times within a predetermined time period, thereby generating a current signal through the battery 110. The battery 110 comprises a plurality of battery cells B₁ . . . Bₙ and each switching element of the plurality 130 of switching elements SW₁ . . . SWₙ is arranged in parallel with at least one battery cell of the plurality of battery cells B₁ . . . Bₙ. The switch-on times are determined by a controller circuit 120. It is thus possible to modulate a load resistance of the battery 110 by controlling the switching elements already available in the common balancing circuits of the battery system 100. When the switching operations are repeated several times, the predetermined time period is also the period of the resulting periodic signal. The shape of the load resistance determines the shape of the excitation current. By varying the switch-on times, various types of excitation currents can be obtained. The controller circuit 120 may select a predetermined number of switching elements to be switched on during the predetermined time period T. In one example, the number of switching elements is equal to 200 and the controller circuit 120 selects four switching elements to be switched on during the predetermined time period T. The switching elements may be controlled by the same local controller 122 of the controller circuit 120. A higher number of switching elements leads to a smoother current signal, but increases the overall energy consumption and the wearing of the switching elements. The switching elements may also be determined pseudo-randomly. During the process, no external current flows through the battery 110. In one example, the battery 110 does not have any external load.

In one example, the switching elements SW₁ . . . SWₙ are switched on during a first half of the predetermined time period. The controlling circuit may send a binary balancing signal that has a low value, i.e. “0”, that indicates that the switching elements should not be switched on, and a high value, i.e. “1”, that indicates that the switching elements can be switched on. The resulting load resistance curve will thus rise during the first half of the predetermined time period.

In one example, a first half of the switching elements SW₁ . . . SWₙ are switched on during a first quarter of the predetermined time period. With this, a symmetrical shape of the excitation current can be obtained.

In one example, the controller circuit 120 determines the switch-on times such that the switch-on times are evenly distributed within the first half of the predetermined time period. A uniform distribution of the switch-on times leads to a constant rise of the load resistance. With this, a triangular shape of the excitation current can be obtained.

In another example, the controller circuit 120 determines the switch-on times such that a first temporal distance between two first consecutive switch-on times is different from a second temporal distance between two second consecutive switch-on times. The switch-on times are thus not evenly distributed. This makes it possible to obtain further shapes of the excitation current, in particular a step-edge shape or a sinusoidal shape.

The controller circuit 120 may determine the switch-on times such that a temporal distance between two consecutive switch-on times decreases during a first portion of the predetermined time period and increases during a second portion of the predetermined time period. With this, a steeper slope of the resulting excitation current can be obtained and the edges of the current curve can be rounded. This can help reducing energy losses when determining the impedance of the battery 110. The increase and the decrease of the switch-on times may be linear. With this, a sinusoidal shape of the excitation current can be approximated. The switch-on times may also increase and decrease according to other mathematical functions, such as polynomial or exponential functions. With this, it is possible to tune the characteristics of the desired excitation current curve, such as the form of the slope and of the edges of the curve.

In one example, at least one of the switch-on times is determined, at least partially, pseudo-randomly. The switch-on times may be deterministically determined by the controller circuit 120 and variations of these switch-on times may be determined pseudo-randomly. In one example, the controller circuit 120 comprises a pseudo-random generator configured to pseudo-randomly determine the variations of the switch-on times. With this, an artificial noise can be generated, which can be used to reduce the overall noise due to the components or the communication delays between the components.

In one example, the process 1000 further comprises switching off the plurality of switching elements SW₁ . . . SWₙ at corresponding switch-off times of the predetermined time period. A temporal distance between the switch-off time and the switch-on time of each switching element may be equal to the half of predetermined time period T. With this, a symmetrical current signal can be generated. In one example, the switch-off times are determined by the controller circuit 120. In another example, the controller circuit 120 comprises a main controller 121 and a plurality of local controller 122. The main controller 121 determines the switch-on times of the switching elements and send corresponding signals to the local controllers 122. The local controllers 122 control the switching elements to be switched on at the switch-on times and to be switched off after a switching period, which may be equal to the predetermined time period. In one example, the switching elements SW₁ . . . SWₙ are switched off during a second half of the predetermined time period T.

In one example, an order, in which the switching elements SW₁ . . . SWₙ are switched on and off, is determined by the controller circuit 120. With this, it is possible to monitor in a simple manner the loading of the switching elements and to prevent some switching elements to be loaded more than the others. Alternatively, an order, in which the switching elements SW₁ . . . SWₙ are switched on and off, is determined pseudo-randomly. This can reduce a complexity of the calculation of the controller circuit 120.

In one example, the controller circuit 120 switches the switching elements SW₁ . . . SWₙ such that, over a plurality of predetermined time periods, the switching elements SW₁ . . . SWₙ are uniformly loaded. This can prevent deterioration of the switching elements. In one example, the switching elements are uniformly loaded over ten impedance measurements. In one example, the switching elements are uniformly loaded over a period of one week.

The process 1000 further comprises the step 1020 of measuring a voltage signal over the battery 110. In one example, the voltage signal is measured over the entire battery. In another example, the measuring the voltage signal comprises: measuring a plurality of partial voltage signals, wherein each partial voltage signal is measured over at least one battery cell of the plurality of battery cells B₁ . . . Bₙ, and adding the partial voltage signals to form the voltage signal. The partial voltage signal may be measured by local controllers 122 of the controller circuit 120, which are coupled to the balancing circuits of the battery 110.

The process 1000 also comprises the step 1030 of determining an impedance of the battery 110 based on the measured voltage signal and on the generated current signal. The current signal may be measured by a corresponding current sensor. However, since the components of the balancing circuits are known, the current signal may also be calculated or evaluated by the controller circuit 120.

The present application describes a method for generating a current curve as an excitation signal for electrochemical impedance spectroscopy on a network of battery cells of a multi-cell battery. For this purpose, switching elements of the available balancing circuits for monitoring the operation of the battery may be controlled collectively to modulate an internal load of the battery. Since the switching elements are part of the existing hardware of battery management systems, there is no need to add further circuitry. A controller circuit specifies the switch-on times of the switching elements in order to generate various signal shapes for the excitation of the entire battery. By switching on the switching elements such that the temporal distance between two consecutive switch-on times remains constant, a triangular shape of the excitation signal can be obtained. When the temporal distance between two consecutive switch-on times is not constant, other shapes of the excitation signal can be obtained, such as a sinusoidal or a step-edge shape. The predetermined time period during which the switching elements are switched on and off corresponds to the period of the resulting signal. When a first half of the switching elements is switched on during a first quarter of the predetermined time period and the selected switching elements are all switched on during a first half of the predetermined time period, a symmetrical signal can be generated. An artificial noise may be generated by combining a deterministic and a pseudo-random determination of the switch-on times. With this, an actual signal noise can be reduced. In order to prevent deterioration of the switching elements, the controller circuit may switch the switching elements such that, over a plurality of predetermined time periods, the switching elements are uniformly loaded. Since the measurement is carried out using a plurality of balancing circuits, the overall power loss will be shared by the different balancing circuits, thus preventing the formation of hot spots in the battery and enabling a good heat dissipation. Further, since the switching operations are spread over time, the electromagnetic properties of the battery do not experience any undesired variations.

Although various embodiments have been illustrated and described with respect to one or more specific implementations, alterations and/or modifications may be made to the illustrated examples without departing from the spirit and scope of the features and structures recited herein. With particular regard to the various functions performed by the above described components or structures (units, assemblies, devices, circuits, systems, etc.), the terms (including a reference to a “means”) used to describe such components are intended to correspond-unless otherwise indicated-to any component or structure that performs the specified function of the described component (e.g., that is functionally equivalent), even if it is not structurally equivalent to the disclosed structure that performs the function in the herein illustrated exemplary implementations of the present disclosure. Furthermore, the methods of the application may be achieved in either all software implementations using the appropriate processor instructions or in hybrid implementations that utilize a combination of hardware logic and software logic to achieve the same results.

Although the present disclosure is not so limited, the following numbered examples demonstrate one or more aspects of the disclosure.

Example 1. A method, comprising: switching on a plurality (130) of switching elements (SW₁, SW₂, . . . , SWₙ) coupled to a battery (110) at corresponding switch-on times within a predetermined time period, thereby generating a current signal through the battery (110), wherein the battery (110) comprises a plurality of battery cells (BC₁, BC₂, . . . , BCₙ) and each switching element of the plurality (130) of switching elements (SW₁, SW₂, . . . , SWₙ) is arranged in parallel with at least one battery cell of the plurality of battery cells (BC₁, BC₂, . . . , BCₙ), wherein the switch-on times are determined by a controller circuit (120); measuring a voltage signal over the battery (110); and determining an impedance of the battery (110) based on the measured voltage signal and on the generated current signal.

Example 2. The method of example 1, wherein the switching elements (S₁, S₂, . . . , Sₙ) are switched on during a first half of the predetermined time period.

Example 3. The method of example 1 or 2, wherein a first half of the switching elements (SW₁, SW₂, . . . , SWₙ) are switched on during a first quarter of the predetermined time period.

Example 4. The method of any one of examples 1 to 3, wherein the controller circuit (120) determines the switch-on times such that the switch-on times are evenly distributed within the first half of the predetermined time period.

Example 5. The method of any one of examples 1 to 3, wherein the controller circuit (120) determines the switch-on times such that a first temporal distance between two first consecutive switch-on times is different from a second temporal distance between two second consecutive switch-on times.

Example 6. The method of any one of examples 1 to 3 or 5, wherein the controller circuit (120) determines the switch-on times such that a temporal distance between two consecutive switch-on times decreases during a first portion of the predetermined time period and increases during a second portion of the predetermined time period.

Example 7. The method of any one of examples 1 to 6, wherein at least one of the switch-on times is determined, at least partially, pseudo-randomly.

Example 8. The method of any one of claims 1 to 7, further comprising: switching off the plurality of switching elements (SW₁, SW₂, . . . , SWₙ) at corresponding switch-off times of the predetermined time period, wherein a temporal distance between the switch-off time and the switch-on time of each switching element is equal to the half of predetermined time period.

Example 9. The method of any one of examples 1 to 8, further comprising: switching off the plurality of switching elements (SW₁, SW₂, . . . , SWₙ) at corresponding switch-off times of the predetermined time period, wherein the switch-off times are deter-mined by the controller circuit (120).

Example 10. The method of example 8 or 9, wherein the switching elements (SW₁, SW₂, . . . , SWₙ) are switched off during a second half of the predetermined time period.

Example 11. The method of any one of examples 1 to 10, wherein an order, in which the switching elements (SW₁, SW₂, . . . , SWₙ) are switched on and off, is determined by the controller circuit (120).

Example 12. The method of any one of examples 1 to 10, wherein an order, in which the switching elements (SW₁, SW₂, . . . , SWₙ) are switched on and off, is determined pseudo-randomly.

Example 13. The method of any one of examples 1 to 12, wherein the measuring the voltage signal comprises: measuring a plurality of partial voltage signals, wherein each partial voltage signal is measured over at least one battery cell of the plurality of battery cells (B₁, B₂, . . . , Bₙ), and adding the partial voltage signals to form the voltage signal.

Example 14. The method of any one of examples 1 to 13, wherein the controller circuit (120) switches the switching elements (SW₁, SW₂, . . . , SWₙ) such that, over a plurality of predetermined time periods, the switching elements (SW₁, SW₂, . . . , SWₙ) are uniformly loaded.

Example 15. A system (100) comprising: a battery (110), wherein the battery (110) comprises a plurality of battery cells (BC₁, BC₂, . . . , BCₙ); a plurality (130) of switching elements (SW₁, SW₂, . . . , SWₙ) coupled to the battery (110), wherein each switching element (SW₁, SW₂, . . . , SWₙ) of the plurality (130) of switching elements (SW₁, SW₂, . . . , SWₙ) is arranged in parallel with at least one battery cell of the plurality of battery cells (BC₁, BC₂, . . . , BCₙ); a controller circuit (120) coupled to the plurality (130) of switching elements (SW₁, SW₂, . . . , SWₙ), wherein the controller circuit (120) is configured to: switch on, at corresponding switch-on times of a predetermined time period, the plurality (130) of switching elements (SW₁, SW₂, . . . , SWₙ), thereby generating a current signal through the battery (110), wherein the switch-on times are determined by the controller circuit (120); measure a voltage signal over the battery (110); and determine an impedance of the battery (110) based on the measured voltage signal and the generated current signal.

Example 16. The system (100) of example 15, further comprising: a plurality of resistors (R_{B1}, R_{B2}, . . . , R_{Bn}), wherein each switching element of the plurality (130) of switching elements (SW₁, SW₂, . . . , SWₙ) is arranged in series with at least one resistor of the plurality of resistors (R_{B1}, R_{B2}, . . . , R_{Bn}).

Example 17. The system (100) according to example 15 or 16, wherein the controller circuit (120) comprises a main controller (121) and a plurality of local controllers (122), wherein a first local controller of the plurality of local controllers (122) is connected to the main controller (121) and the local controllers (122) are connected to each other to form a daisy chain, and wherein each local controller (122) is coupled to at least one switching element of the plurality of switching elements (SW₁, SW₂, . . . , SWₙ) and configured to switch on the corresponding switching element based on at least a signal of the main controller (121).

Example 18. The system according to example 17, wherein each local controller (122) is configured to switch off the corresponding switching element, wherein a temporal distance between the switch-off time and the switch-on time of the corresponding switching element is equal to a half of the predetermined time period.

Example 19. The system according to any one of examples 15 to 18, wherein the controller circuit (120) comprises a plurality of local voltage sensors, wherein each local voltage sensor is configured to measure a local voltage signal over at least one battery cell of the plurality of battery cells (BC₁, BC₂, . . . , BCₙ).

1. A method, comprising:
switching on a plurality of switching elements coupled to a battery at corresponding switch-on times within a predetermined time period, thereby generating a current signal through the battery, wherein the battery (110) comprises a plurality of battery cells and each switching element of the plurality of switching elements is arranged in parallel with at least one battery cell of the plurality of battery cells, wherein the switch-on times are determined by a controller circuit;
measuring a voltage signal over the battery; and
determining an impedance of the battery based on the measured voltage signal and on the generated current signal.

2. The method of claim 1,
wherein the switching elements are switched on during a first half of the predetermined time period.

3. The method of claim 1,
wherein a first half of the switching elements are switched on during a first quarter of the predetermined time period.

4. The method of claim 1,
wherein the controller circuit is configured to determine the switch-on times such that the switch-on times are evenly distributed within the first half of the predetermined time period.

5. The method of claim 1,
wherein the controller circuit is configured to determine the switch-on times such that a first temporal distance between two first consecutive switch-on times is different from a second temporal distance between two second consecutive switch-on times.

6. The method of claim 1,
wherein the controller circuit is configured to determine the switch-on times such that a temporal distance between two consecutive switch-on times decreases during a first portion of the predetermined time period and increases during a second portion of the predetermined time period.

7. The method of claim 1,
wherein at least one of the switch-on times is determined, at least partially, pseudo-randomly.

8. The method of claim 1, further comprising:
switching off the plurality of switching elements at corresponding switch-off times of the predetermined time period, wherein a temporal distance between the switch-off time and the switch-on time of each switching element is equal to the half of predetermined time period.

9. The method of claim 1, further comprising:
switching off the plurality of switching elements at corresponding switch-off times of the predetermined time period, wherein the switch-off times are determined by the controller circuit.

10. The method of claim 9,
wherein the switching elements are switched off during a second half of the predetermined time period.

11. The method of claim 1,
wherein an order, in which the switching elements are switched on and off, is determined by the controller circuit.

12. The method of claim 1,
wherein an order, in which the switching elements are switched on and off, is determined pseudo-randomly.

13. The method of claim 1,
wherein the measuring the voltage signal comprises: measuring a plurality of partial voltage signals, wherein each partial voltage signal is measured over at least one battery cell of the plurality of battery cells, and adding the partial voltage signals to form the voltage signal.

14. The method of claim 1,
wherein the controller circuit switches the switching elements such that, over a plurality of predetermined time periods, the switching elements are uniformly loaded.

15. A system comprising:
a battery, wherein the battery comprises a plurality of battery cells;
a plurality of switching elements coupled to the battery, wherein each switching element of the plurality of switching elements is arranged in parallel with at least one battery cell of the plurality of battery cells;
a controller circuit coupled to the plurality of switching elements, wherein the controller circuit is configured to:
switch on, at corresponding switch-on times of a predetermined time period, the plurality of switching elements, thereby generating a current signal through the battery, wherein switch-on times are determined by the controller circuit;
measure a voltage signal over the battery; and
determine an impedance of the battery based on the measured voltage signal and the generated current signal.

16. The system of claim 15, further comprising:
a plurality of resistors, wherein each switching element of the plurality of switching elements is arranged in series with at least one resistor of the plurality of resistors.

17. The system according to claim 15,
wherein the controller circuit comprises a main controller and a plurality of local controllers,
wherein a first local controller of the plurality of local controllers is connected to the main controller and the local controllers are connected to each other to form a daisy chain, and
wherein each of the local controllers is coupled to at least one switching element of the plurality of switching elements and configured to switch on a corresponding switching element based on at least a signal of the main controller.

18. The system according to claim 17,
wherein each of the local controllers is configured to switch off the corresponding switching element, wherein a temporal distance between the switch-off time and the switch-on time of the corresponding switching element is equal to a half of the predetermined time period.

19. The system according to claim 15,
wherein the controller circuit comprises a plurality of local voltage sensors, wherein each of the local voltage sensors is configured to measure a local voltage signal over at least one battery cell of the plurality of battery cells.
